(19) United States
(12) Patent Application Publication
(10) Pub. No.: US 2014/0174350 A1
(43) Pub. Date: Jun. 26, 2014

(54) VAPOR DEPOSITION APPARATUS

(71) Applicants: Sang Kyu Bang, Hwasung-si (KR); Chin Wook Chon, Yongin-si (KR); Kyung Don Han, Suwon-si (KR); Jong Wook Suk, Hwasung-si (KR); Sung Il Han, Suwon-si (KR)

(72) Inventors: Sang Kyu Bang, Hwasung-si (KR); Chin Wook Chon, Yongin-si (KR); Kyung Don Han, Suwon-si (KR); Jong Wook Suk, Hwasung-si (KR); Sung Il Han, Suwon-si (KR)

(73) Assignee: SAMSUNG ELECTRONICS CO., LTD., Suwon-si, Gyeonggi-do (KR)

(21) Appl. No.: 14/237,855

(22) PCT Filed: Aug. 9, 2011
(86) PCT No.: PCT/KR2011/005773

§ 371 Date: Feb. 7, 2014

(51) Int. Cl. C30B 25/12

(52) U.S. Cl. CPC C30B 25/12
USPC 118/712; 118/728; 118/730

(57) ABSTRACT

There is provided a vapor phase deposition apparatus including: a reaction chamber having a susceptor with a wafer mounted thereon and depositing and growing an epitaxial thin film on the wafer; a housing having the reaction chamber disposed therein and having a window opened and closed to allow the wafer to be loaded into or unloaded from the wafer reaction chamber; and an exhaust unit discharging gas from within the housing to the outside to adjust internal pressure of the housing.

### TECHNICAL FIELD

The present disclosure relates to a vapor phase growth apparatus, and more particularly, to a vapor phase deposition apparatus capable of facilitating precise handling of a wafer as an object to be deposited to thus enhance work efficiency.

### BACKGROUND ART

Recently, as demand for miniaturization of semiconductor devices and development of high efficiency and high output LED has increased, a vapor phase deposition apparatus (chemical vapor deposition (CVD) or metal organic chemical vapor deposition (MOCVD)) allowing for mass-production without degradation of quality and performance is being required.

In general, vapor deposition refers to a scheme in which a reactive gas supplied to an interior of an airtight reaction chamber chemically reacts on an upper surface of a heated wafer to deposit and grow an epitaxial thin film on the surface of the wafer.

In order to install a wafer in a reaction chamber disposed in a space isolated from the outside such as a glove box or to replace a wafer after deposition, an operation should be performed in a state in which a thick glove provided in the glove box is worn, making it difficult to precisely handle a wafer and degrading reliability of quality as a defect occurs.

In addition, since the interior of the glove box is maintained at a pressure higher than normal atmospheric pressure, excessive force needs to be applied to precisely control a wafer, making the operation difficult. Also, in order to replace a component, clean the interior, or the like, the operation needs to be stopped and the glove box needs to be disassembled, so device maintenance is not easy and productivity is degraded.

In addition, in order to supply a wafer to the interior of the glove box isolated from the outside, a pass box needs to be connected to the glove box to maintain internal pressure, thus increasing cost.

### DISCLOSURE

### Technical Problem

An aspect of the present disclosure provides a vapor deposition apparatus capable of precisely controlling handling of a wafer such as installation of a wafer for deposition and removal of the wafer after deposition, and facilitating replacement of a component, cleaning, or the like, to thus facilitate maintenance.

### Technical Solution

According to an aspect of the present disclosure, there is provided a vapor phase deposition apparatus including: a reaction chamber having a susceptor with a wafer mounted thereon and depositing and growing an epitaxial thin film on the wafer; a housing having the reaction chamber disposed therein and having a window opened and closed to allow the wafer to be loaded into or unloaded from the wafer reaction chamber; and an exhaust unit discharging gas from within the housing to the outside to adjust internal pressure of the housing.

One or more windows may be disposed in the proximity of the reaction chamber and may be disposed to face the reaction chamber.

The window may have a structure sloped at a predetermined tilt toward an upper portion of the housing.

The vapor phase deposition apparatus may further include a driving unit moving the window vertically or horizontally with respect to a lower portion of the housing to open or close the window.

The exhaust unit may include a vent hood connected to a vent pipe extending to an interior of the housing so as to be adjusted in position and a gate valve connected to the vent pipe to exhaust the interior of the housing.

The vapor phase deposition apparatus may further include a sensor sensing internal and external states of the housing.

The vapor phase deposition apparatus may further include a controller controlling rotation of the susceptor, opening and closing of the reaction chamber and the housing, and an operation of the exhaust unit.

### Advantageous Effects

According to an exemplary embodiment of the present disclosure, since an operator may handle a wafer directly from outside of a housing without having to wear a thick glove, precise controlling may be performed, and thus, product reliability may be enhanced.

In addition, since an operator performs an operation by opening a window of the housing, replacement of a component and a cleaning operation may be easily performed, and thus, device maintenance may be facilitated and productivity may be enhanced.

Also, since an additional element such as a pass box is not required, cost is reduced.

### DESCRIPTION OF DRAWINGS

FIG. 1 is a perspective view schematically illustrating a vapor deposition device according to an exemplary embodiment of the present disclosure;

FIG. 2 is a front view illustrating the vapor deposition apparatus of FIG. 1;

FIG. 3 is a plan view illustrating the vapor deposition apparatus of FIG. 1;

FIG. 4 is a front perspective view illustrating a window of the vapor deposition apparatus of FIG. 1;

FIG. 5 is a rear perspective view illustrating the window of FIG. 4; and

FIG. 6 is a view illustrating another example of the window of the vapor deposition apparatus of FIG. 1.

### BEST MODE

Hereinafter, a vapor phase deposition apparatus according to an exemplary embodiment of the present disclosure will be described with reference to the accompanying drawings.

The disclosure may, however, be exemplified in many different forms and should not be construed as being limited to the specific exemplary embodiments set forth herein. Rather, these exemplary embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

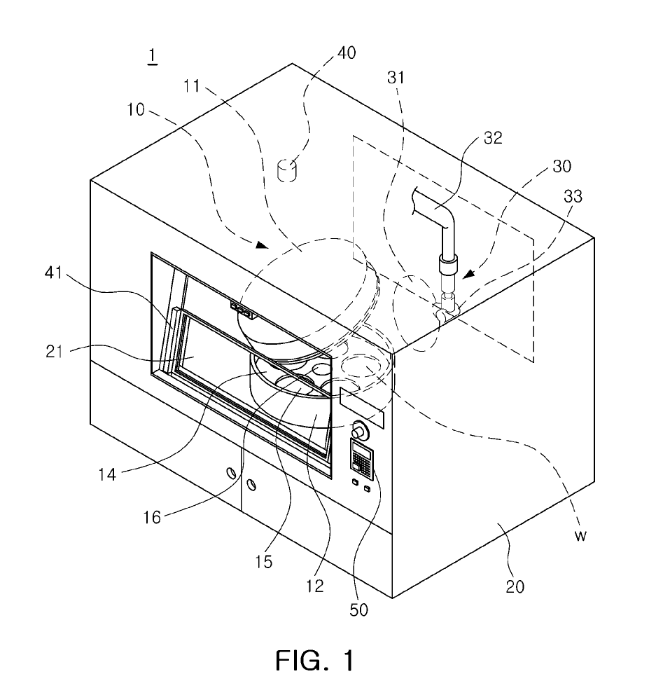

A vapor phase deposition apparatus according to an exemplary embodiment of the present disclosure will be described with reference to FIGS. 1 through 6.

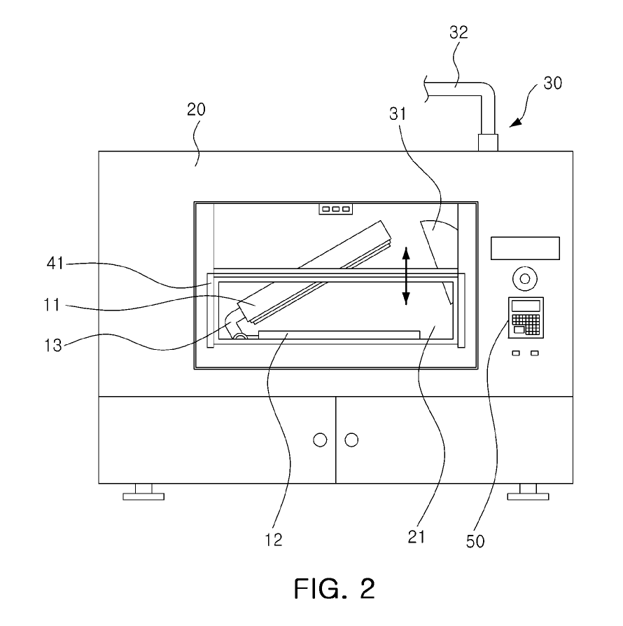

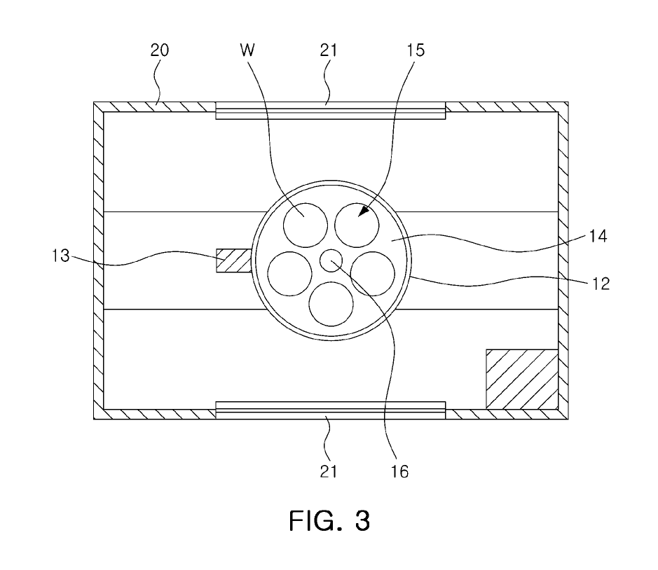

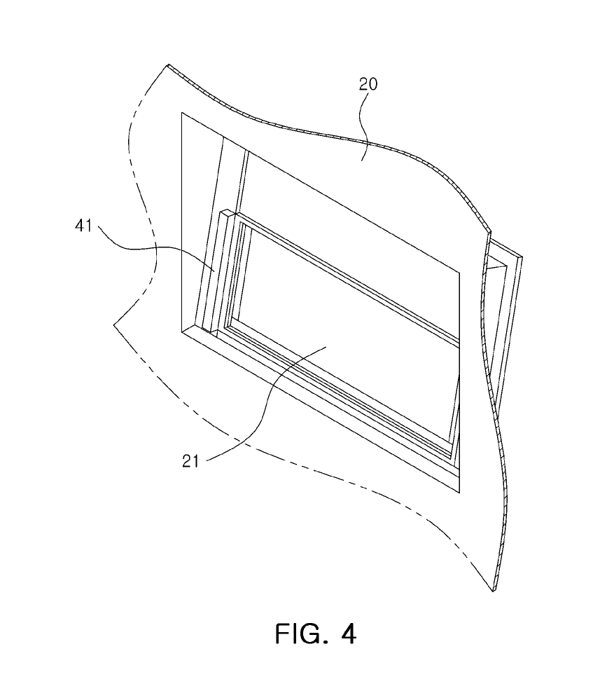

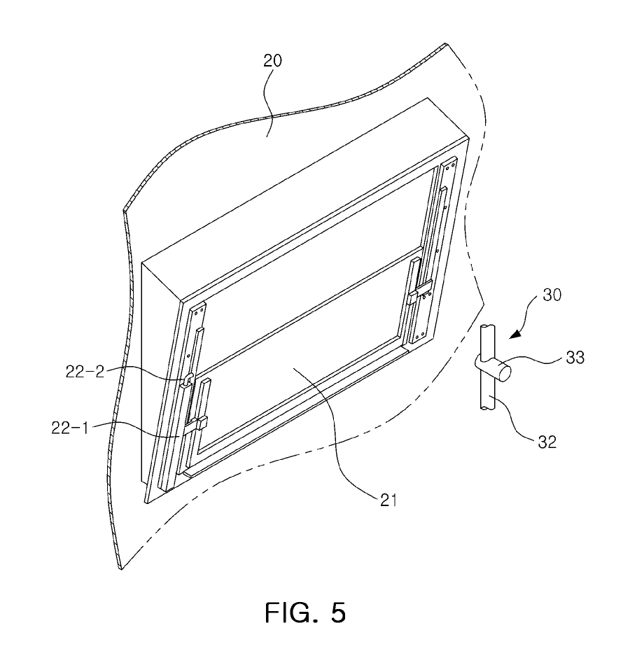

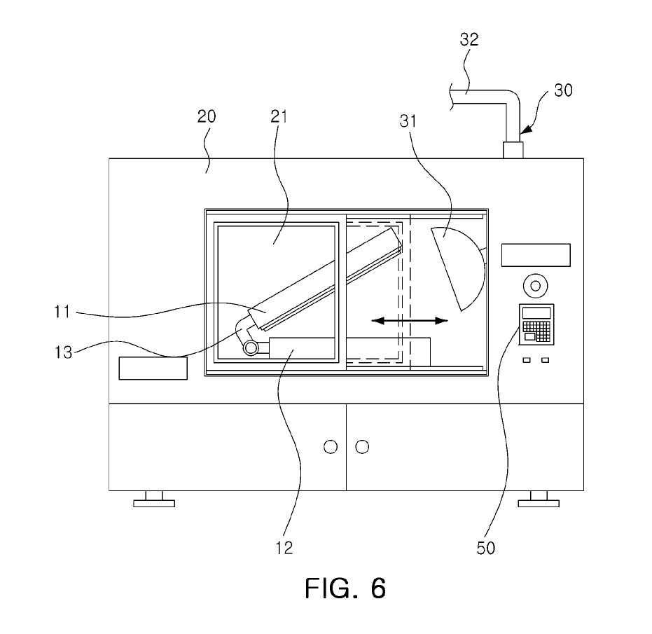

FIG. 1 is a perspective view schematically illustrating a vapor deposition device according to an exemplary embodiment of the present disclosure, FIG. 2 is a front view illustrating the vapor deposition apparatus of FIG. 1, and FIG. 3 is a plan view illustrating the vapor deposition apparatus of FIG. 1. FIG. 4 is a front perspective view illustrating a window of the vapor deposition apparatus of FIG. 1, FIG. 5 is a rear perspective view illustrating the window of FIG. 1, and FIG. 6 is a view illustrating another example of the window of the vapor deposition apparatus of FIG. 1.

Referring to FIGS. 1 through 6, a vapor phase deposition apparatus 1 according to an exemplary embodiment of the present disclosure may include a reaction chamber 10, a housing 20, and an exhaust unit 30.

The reaction chamber 10 is a vertically cylindrical structure including an upper cover 11 and a lower cover 12 assembled to form a hermetically closed internal space having a predetermined size. The downwardly opened upper cover 11 and the upwardly opened lower cover 12 may be formed of a metal having excellent abrasion resistance and corrosion resistance, and may have an insulating material (not shown) formed therein. A cover rotating unit 13 may be provided on one side of the reaction chamber 10 to rotate any one of the upper cover 11 and the lower cover 12 to separate or assemble them.

A susceptor 14 including one or more pockets 15 formed to be depressed on an upper surface thereof is rotatably provided within the reaction chamber 10. Wafers W are loaded in the pockets 15. The susceptor 14, a wafer supporting structure, is formed of graphite and has a disk shape. A rotational shaft 16 connected to a driving motor (not shown) is provided in a center of a lower surface of the susceptor 14, such that the susceptor 14 with the wafers W loaded therein may be uniformly rotated at a constant speed in one direction by rotary power of the driving motor.

In a state in which the upper cover 11 and the lower cover 12 of the reaction chamber 10 are hermetically closed, a reactive gas introduced to the interior of the reaction chamber 10 through a gas supply unit (not shown) undergoes a chemical vapor phase reaction with the wafers W as deposition targets to deposit and grow epitaxial thin films on upper surfaces of the wafers W.

Meanwhile, the housing 20 is a box-shaped structure providing an internal space having a predetermined size in which the reaction chamber 10 is disposed, protecting the reaction chamber 10 from an ambient environment during a deposition process and preventing the reaction chamber 10 from coming in contact with an ambient environment.

In detail, the housing 20 includes a window 21 that may be opened and closed to allow the wafer W to be easily loaded into the susceptor 14 of the reaction chamber 10 from the outside or unloaded therefrom. Namely, instead of wearing thick rubber gloves and laboriously handling a wafer W from the outside of a conventional glove box in a hermetically closed state isolated from outside, rubber gloves are eliminated and the window 21 that may be opened and closed is provided at a corresponding position, whereby the window 21 may be opened to open the interior of the housing 20 and the wafer W may be directly loaded and unloaded. Thus, handling of the wafer W within the reaction chamber 10 may be precisely and easily performed outside of the housing 20. Also, the interior of the reaction chamber 10 and the interior of the housing 20 may easily be cleaned and components thereof may easily be replaced, obtaining advantages of facilitating maintenance of the apparatus.

The window 21 may be formed of a firm transparent material allowing the interior to be visible, such as compressed plastic or tempered glass. One or more windows 21 may be provided in the proximity of the reaction chamber and disposed to face the reaction chamber 10. As illustrated in FIGS. 2 and 3, the windows 21 may be provided in front and rear surfaces of the housing 20 with the reaction chamber 10 interposed therebetween. Alternatively, the window 21 may be provided only in the front surface of the housing 20 or may also be provided in a lateral surface of the housing 20.

The window 21 may be provided as having a vertical structure level with one surface of the housing 20, or alternatively, may have a structure inwardly sloped at a predetermined tilt toward an upper surface of the housing 20 as illustrated in FIGS. 4 and 5. In this case, the reaction chamber 10 within the housing 20, specifically, the interior of the reaction chamber 10 and the susceptor 14 therein, may be more easily viewed from structurally outside the housing 20, and thus, the wafer W may be installed at an accurate position.

As illustrated in FIG. 1, the window 21 may be vertically moved in a longitudinal direction so as to be opened and closed with respect to a lower portion of the housing 20, or as illustrated in FIG. 6, the window 21 may be horizontally moved in a transverse direction. To this end, a driving unit 22 may be provided to vertically or horizontally move the window 221 in order to open or close it with respect to the lower portion of the housing 20. A cylinder member 22-1 having a piston 22-2 may be employed as the driving unit 22. Thus, by reciprocating the piston 22-2 by driving the cylinder member 22-1, the window 21 connected to the piston 22-2 may be moved to be opened and closed.

In this manner, the window 21 may be automatically opened and closed through the driving unit 22, and also, the window 21 may be opened and closed only when a particular condition is satisfied, whereby the window 21 is prevented from being arbitrarily opened and closed, promoting stability of an operation. In addition, since the wafer W may be directly carried into or out of the housing through the window 21, equipment such as a pass box, or the like, may be omitted.

The exhaust unit 30 discharges a gas in the interior of the housing 20 to the outside in order to adjust internal pressure of the housing 20. The exhaust unit 30 may be provided in an upper surface of the housing 20, but the present disclosure is not limited thereto.

As illustrated, the exhaust unit 30 may include a vent hood 31 connected to a vent pipe 32 extending to the interior of the housing 20 and adjusted in position and a gate valve 33 connected to the vent pipe 32 to exhaust air from the interior of the housing 20.

Thus, when the window 21 is opened to install and replace the wafer W, the gate valve 33 may be opened to discharge a gas within the housing 20 outwardly through the vent hood 31 and the vent pipe 32 to adjust internal pressure of the housing 20 to have a pressure level (−2 mBar) lower than or equal to atmospheric pressure. Here, harmful gas within the housing 20 is discharged through the exhaust unit 30, promoting environmental safety.

Meanwhile, the housing 20 may have sensor units 40 and 41 to sense an internal state such as internal temperature, internal pressure, leakage of hydrogen (H₂) gas, the presence or absence of harmful gas, and the like, and an external state such as whether the window 21 is opened or whether an operator is working. When an internal state of the housing 20 is sensed through the sensor units and 41 and a particular condition is satisfied, the window 21 may be opened, and in a case in which the operator is working with the window 21 opened, the window 21 is prevented from being arbitrarily closed.

For example, when leakage of H₂ having a possibility of explosion is sensed through the sensor units 40 and 41, an open state of the upper cover 11 of the reaction chamber 10 having completely undergone a process is checked, the gate valve 33 is opened to discharge gas within the housing 20, it is determined whether internal pressure of the housing 20 is maintained at a pressure level (−2 mBar) lower than atmospheric pressure, and thereafter, the window 21 is allowed to be opened automatically. In a case in which the window 21 is open, when leakage of H₂ gas is sensed and an internal temperature exceeds a pre-set temperature (e.g., 50° C.), whether an operator is present or absent is checked through the sensor unit 41 such as a light curtain installed in the window 21, and the window 21 is controlled to be closed automatically, thus promoting safety.

Also, the housing 20 may control rotation of the susceptor 14, opening and closing of the reaction chamber 10, and an operation of the exhaust unit 30, as well as automatically controlling opening and closing of the window 21 through a controller 50 connected to the sensor units 40 and 41.

1.-7. (canceled)

8. A vapor phase deposition apparatus, comprising:
a reaction chamber having a susceptor with a wafer mounted thereon and depositing and growing an epitaxial thin film on the wafer;
a housing having the reaction chamber disposed therein and having a window opened and closed to allow the wafer to be loaded into or unloaded from the reaction chamber; and
an exhaust unit discharging gas from within the housing to the outside to adjust internal pressure of the housing.

9. The vapor phase deposition apparatus of claim 8, wherein one or more windows are disposed in the proximity of the reaction chamber and are disposed to face the reaction chamber.

10. The vapor phase deposition apparatus of claim 9, wherein the one or more windows are provided in front and rear surfaces of the housing with the reaction chamber interposed therebetween, or provided in one of front, rear and lateral surfaces of the housing.

11. The vapor phase deposition apparatus of claim 8, wherein the window has a structure sloped at a predetermined tilt toward an upper portion of the housing.

12. The vapor phase deposition apparatus of claim 8, further comprising: a driving unit moving the window vertically or horizontally with respect to a lower portion of the housing to open or close the window.

13. The vapor phase deposition apparatus of claim 12, wherein the driving unit comprises a cylinder member having a piston connected to the window.

14. The vapor phase deposition apparatus of claim 8, wherein the exhaust unit comprises a vent hood connected to a vent pipe extending to an interior of the housing so as to be adjusted in position and a gate valve connected to the vent pipe to exhaust the interior of the housing.

15. The vapor phase deposition apparatus of claim 14, wherein the exhaust unit discharges gas within the housing and adjusts internal pressure of the housing to have a pressure level lower than or equal to atmospheric pressure.

16. The vapor phase deposition apparatus of claim 8, further comprising a sensor sensing internal and external states of the housing.

17. The vapor phase deposition apparatus of claim 8, further comprising a controller controlling rotation of the susceptor, opening and closing of the reaction chamber and the housing, and an operation of the exhaust unit.

18. The vapor phase deposition apparatus of claim 8, wherein the reaction chamber comprises an upper cover and a lower cover assembled to form a hermetically closed internal space, and a rotating unit to rotate any one of the upper cover and the lower cover.

19. A vapor phase deposition apparatus, comprising:
a housing having a window; and
a reaction chamber disposed within the housing and having a susceptor with a wafer mounted thereon,
wherein the wafer is loaded into or unloaded from the reaction chamber within the housing through opening and closing of the window.

20. The vapor phase deposition apparatus of claim 19, further comprising a sensor sensing internal and external states of the housing and allows the window to be opened or closed at a determined condition.

21. The vapor phase deposition apparatus of claim 19, further comprising a driving unit moving the window to open or close.

22. The vapor phase deposition apparatus of claim 19, further comprising an exhaust unit discharging gas from within the housing to the outside.
